(19) United States
(12) Patent Application Publication
(10) Pub. No.: US 2026/0143619 A1
(43) Pub. Date: May 21, 2026

(54) Server System Cable Management System

(71) Applicant: Dell Products L.P., Round Rock, TX (US)

(72) Inventors: Walter R. Carver, Round Rock, TX (US); Eduardo Escamilla, Round Rock, TX (US); Jason Pritchard, Hopkinton, MA (US)

(21) Appl. No.: 18/955,037

(22) Filed: Nov. 21, 2024

(51) Int. Cl. H05K 7/14

(52) U.S. Cl. CPC H05K 7/1491; H05K 7/1489

(57) ABSTRACT

A cable management system for use with an information handling system. The cable management system includes a chassis, a cable and a cable management component, the cable management component including a mounting bracket portion, the mounting bracket portion being configured to mount to a side of a chassis when the cable management component is in a cable management configuration and a cable routing portion physically coupled to the mounting bracket portion, the cable routing portion being configured to slide along a cable when the cable management component moves between a stowed configuration and the cable management configuration.

### BACKGROUND OF THE INVENTION

### Field Of The Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a server system with a cable management system.

In one embodiment, the invention relates to a cable management component of a cable management system for an information handling system, comprising: a mounting bracket portion, the mounting bracket portion being configured to mount to a side of a chassis when the cable management component is in a cable management configuration; and; a cable routing portion physically coupled to the mounting bracket portion, the cable routing portion being configured to slide along a cable when the cable management component moves between a stowed configuration and the cable management configuration.

In another embodiment, the invention relates to cable management system for use in an information handling system comprising: a chassis, a cable; and, a cable management component, the cable management component comprising: a mounting bracket portion, the mounting bracket portion being configured to mount to a side of the chassis when the cable management component is in a cable management configuration; and; a cable routing portion physically coupled to the mounting bracket portion, the cable routing portion being configured to slide along the cable when the cable management component moves between a stowed configuration and the cable management configuration.

In another embodiment, the invention relates to a system comprising: a chassis; a cable contained within the chassis; a high performance module; and, a cable management system, the cable management system comprising: a mounting bracket portion, the mounting bracket portion being configured to mount to a side of the chassis when the cable management component is in a cable management configuration; and; a cable routing portion physically coupled to the mounting bracket portion, the cable routing portion being configured to slide along the cable when the cable management component moves between a stowed configuration and the cable management configuration.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIGS. 4A and 4B, generally referred to as FIG. 4, show views of a cable management system.

FIGS. 5A and 5B, generally referred to as FIG. 5, show views of a cable management component.

FIGS. 6A, 6B, 6C, 6D, 6E, 6F, 6G and 6H show views of a cable management component.

### DETAILED DESCRIPTION

Various aspects of the present disclosure include an appreciation that it is known to route one or more cables within information handling systems such as server type information handling systems. Various aspects of the present disclosure include an appreciation that certain known information handling systems include cables that are routed from a lower portion of the information handling system to a high performance module (HPM) which is located in an upper portion of the information handling system. Various aspects of the present disclosure include an appreciation that with certain known information handling systems cables are routed from a lower portion of the information handling system to an upper portion of the information handling system via channels located along the sides of interior of the chassis of the information handling system. Various aspects of the present disclosure include an appreciation that the cables can include peripheral component interconnect express (PCIe) type cables.

Various aspects of the present disclosure include an appreciation that certain known information handling systems include cables that are routed from a lower switchboard to an HPM in an upper portion of the chassis. Various aspects of the present disclosure include an appreciation that with 4U type information handling systems, the switchboard is often located in a lower 3U portion of the chassis and the HPM if often located in an upper U portion of the chassis of the information handling system. With such a system it can be desirable to route the cables through channels located along sides of the interior of the chassis. Various aspects of the present disclosure include an appreciation that with certain information handling system chassis, routing of the cables can be challenging due to, for example, a reduced internal width of certain areas within the chassis. Various aspects of the present disclosure include an appreciation that the reduced internal width may be due to an interaction of a top cover with a bottom portion of the chassis. Various aspects of the present disclosure include an appreciation that the interaction of the top cover with the bottom portion of the chassis can result in a jog and hem associated with the top cover.

Accordingly, various aspects of the present disclosure include an appreciation that it would be desirable to manage cables within a chassis of an information handling system. Accordingly, various aspects of the present disclosure include an appreciation that it would be desirable to manage cables in a cover area of the information handling system. Accordingly, various aspects of the present disclosure include an appreciation that so managing the cables would facilitate the installation of an HPM to the information handling system.

A system and method are disclosed for providing an information handling system with a cable management system. In certain embodiments, the cable management system is integrated into the chassis, facilitating assembly and service. In certain embodiments, the cable management system may be maintained within the chassis in a plurality of configurations. In certain embodiments, the cable management system may be maintained in a stowed configuration when an HPM is installed in the information handling system. In certain embodiments, the cable management system includes a cable management configuration for use when cables need to be managed such as when the HPM is being installed, removed, serviced, or a combination thereof. In certain embodiments, when in the cable management configuration, the cable management system is hung on a chassis side wall to facilitate routing of the one or more cables while allowing access to the HPM.

In certain embodiments, the cable management system includes a cable routing component. In certain embodiments, the cable routing component slides along one or more cables, neatly managing the one or more cables against the reduced cover area of the interior of the chassis. In certain embodiments, the cable routing component stows in place when the HPM is installed and is lifted to hang on the chassis side wall when removing or installing the HPM, thereby ensuring a smooth and hassle-free process.

In certain embodiments, the cable routing component includes a mounting bracket portion, a cable routing portion, or a combination thereof. In certain embodiments, the mounting bracket portion is constructed from metal. In certain embodiments, the cable routing portion is constructed from a thinner material than that of the mounting bracket portion. In certain embodiments, the cable routing portion is constructed from a polyester film such as a polyethylene terephthalate (PET) type material. In certain embodiments, the mounting bracket portion surrounds the cable routing portion along a first side edge, a second side edge, a bottom edge, or a combination thereof.

Such a cable management system advantageously facilitates assembly and service of an information handling system such as a server type information handling system. Such a cable management system advantageously facilitates assembly and service of components located in an upper portion of an information handling system. Such a cable management system advantageously facilitates assembly and service of an HPM of an information handling system.

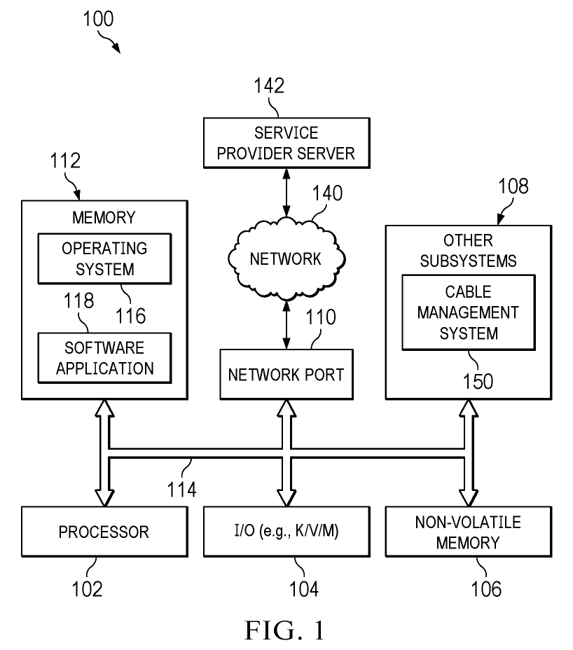

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include a cable management system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the cable management system 150 is integrated into the chassis, facilitating assembly and service. In certain embodiments, the cable management system 150 may be maintained within the chassis in a plurality of configurations. In certain embodiments, the cable management system 150 may be maintained in a stowed configuration when an HPM is installed in the information handling system. In certain embodiments, the cable management system 150 includes a cable management configuration for use when cables need to be managed such as when the HPM is being installed, removed, serviced, or a combination thereof. In certain embodiments, when in the cable management configuration, the cable management system is hung on a chassis side wall to facilitate routing of the one or more cables while allowing access to the HPM.

In certain embodiments, the cable management system 150 includes a cable routing component. In certain embodiments, the cable routing component slides along one or more cables, neatly managing the one or more cables against the reduced cover area of the interior of the chassis. In certain embodiments, the cable routing component stows in place when the HPM is installed and is lifted to hang on the chassis side wall when removing or installing the HPM, thereby ensuring a smooth and hassle-free process.

In certain embodiments, the cable routing component includes a mounting bracket portion, a cable routing portion, or a combination thereof. In certain embodiments, the mounting bracket portion is constructed from metal. In certain embodiments, the cable routing portion is constructed from a thinner material than that of the mounting bracket portion. In certain embodiments, the cable routing portion is constructed from a polyester film such as a polyethylene terephthalate (PET) type material. In certain embodiments, the mounting bracket portion surrounds the cable routing portion along a first side edge, a second side edge, a bottom edge, or a combination thereof.

Such a cable management system advantageously facilitates assembly and service of an information handling system such as a server type information handling system. Such a cable management system advantageously facilitates assembly and service of components located in a upper portion of an information handling systems. Such a cable management system advantageously facilitates assembly and service of an HPM of an information handling system.

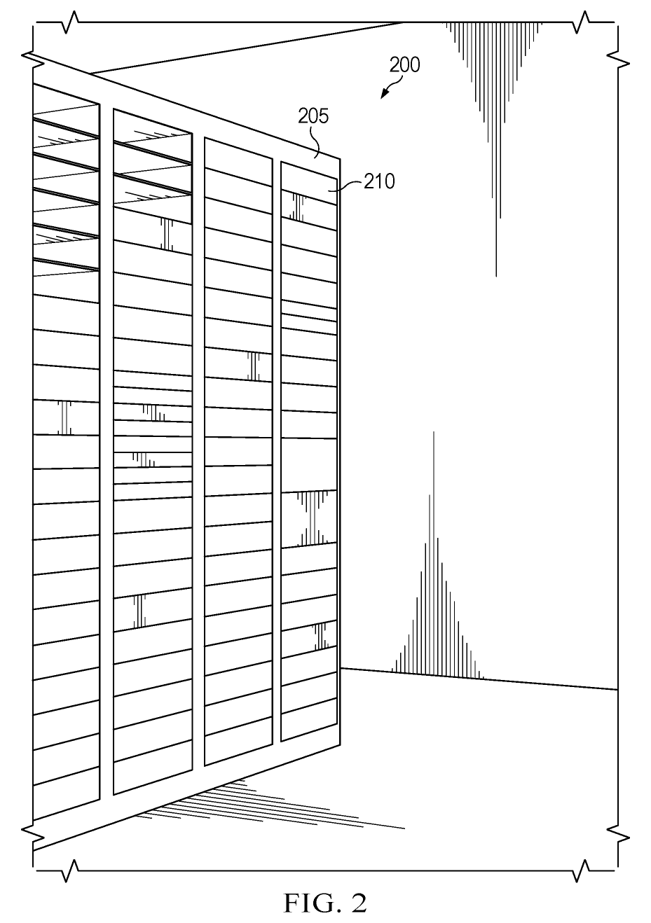

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100, as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit, and a 4U rack unit. In general, a 1U rack unit is substantially (i.e., +/-20%) 1.75” high, a 2U rack unit is substantially (i.e., +/-20%) 3.5” high, and a 4U rack height is substantially (i.e., +/-20%) 7.0” high.

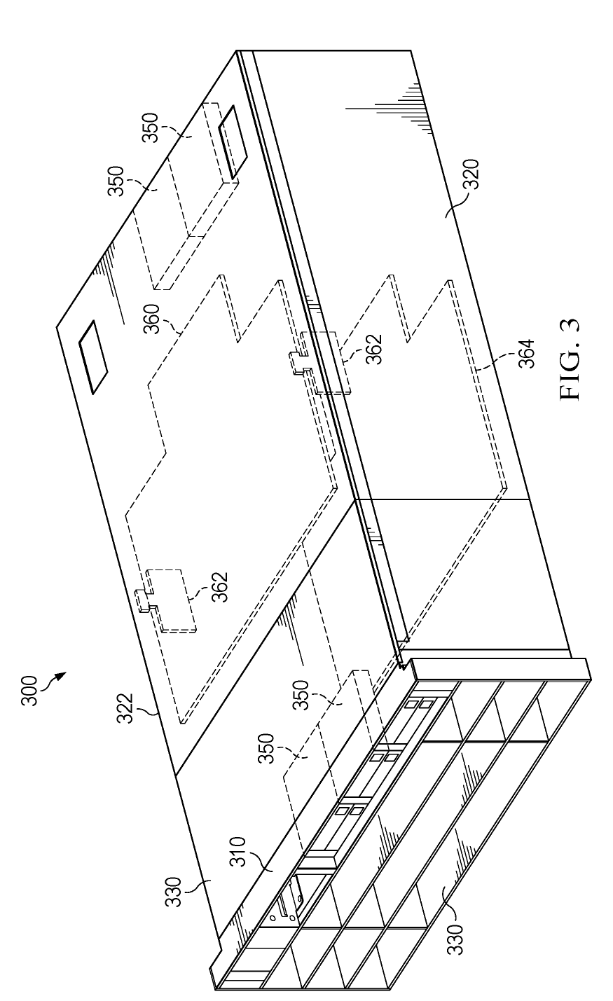

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300.

In certain embodiments, the blade type information handing system 300 includes a one or more device bays 350. In certain embodiments, the information handling system 300 includes a high performance module (HPM) 360 (also referred to as a motherboard or a planar board) as well as one or more cable management systems 362. In certain embodiments, each cable management system 362 corresponds to the cable management system 150. In certain embodiments, the information handling system 300 is configured as a 4U type information handling system. In certain embodiments, the information handling system 300 includes cables that are routed from a lower component 364 to the HPM 360 in an upper portion of the chassis of the information handling system. In certain embodiments, the lower component 364 includes a switchboard component. In certain embodiments, the lower component 364 is located in a lower portion of the chassis (such as a lower 3U portion) and the HPM is located in an upper portion of the chassis (such as an upper 1U portion) of the information handling system. In certain embodiments, the one or more cable management systems 362 route the cables through channels located along sides of an interior of the chassis from the lower portion to the upper portion.

In certain embodiments, the cable management system 362 is integrated into the chassis, facilitating assembly and service. In certain embodiments, the cable management system 362 may be maintained within the chassis in a plurality of configurations. In certain embodiments, the cable management system 362 may be maintained in a stowed configuration when an HPM 360 is installed in the information handling system. In certain embodiments, the cable management system 362 includes a cable management configuration for use when cables need to be managed such as when the HPM 360 is being installed, removed, serviced, or a combination thereof. In certain embodiments, when in the cable management configuration, the cable management system is hung on a chassis side wall to facilitate routing of the one or more cables while allowing access to the HPM 360.

In certain embodiments, the cable management system 362 includes a cable routing component. In certain embodiments, the cable routing component slides along one or more cables, neatly managing the one or more cables against the reduced cover area of the interior of the chassis. In certain embodiments, the cable routing component stows in place when the HPM 360 is installed and is lifted to hang on the chassis side wall when removing or installing the HPM 360, thereby ensuring a smooth and hassle-free process.

In certain embodiments, the cable routing component includes a mounting bracket portion, a cable routing portion, or a combination thereof. In certain embodiments, the mounting bracket portion is constructed from metal. In certain embodiments, the cable routing portion is constructed from a thinner material than that of the mounting bracket portion. In certain embodiments, the cable routing portion is constructed from a polyester film such as a polyethylene terephthalate (PET) type material. In certain embodiments, the mounting bracket portion surrounds the cable routing portion along a first side edge, a second side edge, a bottom edge, or a combination thereof.

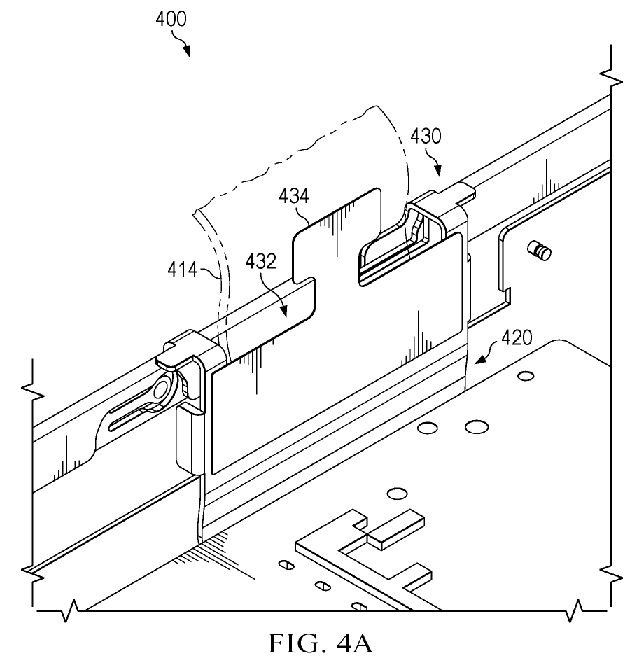

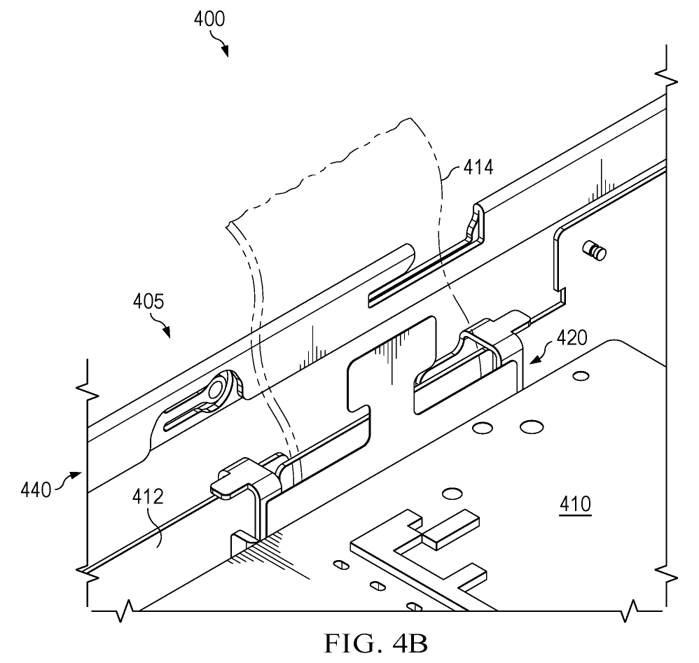

FIGS. 4A and 4B, generally referred to as FIG. 4, show views of a cable management system 400 and a portion of an information handling system chassis 405. More specifically, FIG. 4A shows a perspective view of a cable management system 400 in a cable management configuration. FIG. 4B shows a perspective view of a cable management system 400 in a stowed configuration. In certain embodiments, the cable management system 400 corresponds to cable management system 150.

In certain embodiments, cable management system 400 includes a portion of the chassis 405, a portion of a high performance module (HPM) 410, a portion of a high performance module mounting bracket 412, a cable 414, a cable routing component 420, or a combination thereof. In certain embodiments, the portion of the chassis 405 includes a side wall of the chassis 405. In certain embodiments, the side wall of the chassis and the portion of the high performance module mounting bracket are laterally spaced apart to provide an area through which one or more cables 422 may be passed.

In certain embodiments, the cable routing component 420 is integrated into the information handling system chassis 405, facilitating assembly and service. In certain embodiments, the cable routing component 420 may be maintained within the chassis 405 in a plurality of configurations. In certain embodiments, the cable routing component 420 may be maintained in a stowed configuration when an HPM 410 is installed in the information handling system. In certain embodiments, the cable routing component 420 may be maintained in a cable management configuration for use when cables need to be managed such as when the HPM 410 is being installed, removed, serviced, or a combination thereof. In certain embodiments, when in the cable management configuration, the cable routing component 420 is hung on a chassis side wall to facilitate routing of the one or more cables while allowing access to the HPM 410. In certain embodiments, when moving between the stowed configuration and the cable management configuration, the cable routing component 420 slides along the cable and mounts to the side of the chassis, keeping the cable out of the way during installation or removal of the HPM 410.

In certain embodiments, the cable routing component 420 slides along one or more cables 414, neatly managing the one or more cables 414 against the reduced cover area of the interior of the chassis. In certain embodiments, the cable routing component 420 stows in place when the HPM 410 is installed and is lifted to hang on the chassis side wall when removing or installing the HPM 410, thereby ensuring a smooth and hassle-free process.

In certain embodiments, the cable routing component 420 includes a mounting bracket portion 430, a cable routing portion 432, or a combination thereof. In certain embodiments, the mounting bracket portion 430 is constructed from metal. In certain embodiments, the cable routing portion 432 is constructed from a thinner material than that of the mounting bracket portion 430. In certain embodiments, the cable routing portion 432 is constructed from a polyester film such as a polyethylene terephthalate (PET) type material. In certain embodiments, the cable routing portion 432 includes a pull tab 434 for lifting the cable routing component 420 onto the chassis wall when moving the cable routing component from the stowed configuration to the cable management configuration. In certain embodiments, the mounting bracket portion 430 surrounds the cable routing portion 432 along a first side edge, a second side edge, a bottom edge, or a combination thereof. The cable routing portion 432 provides extra clearance for the cable 414 in the hemmed/jogged area 440 on the chassis side wall.

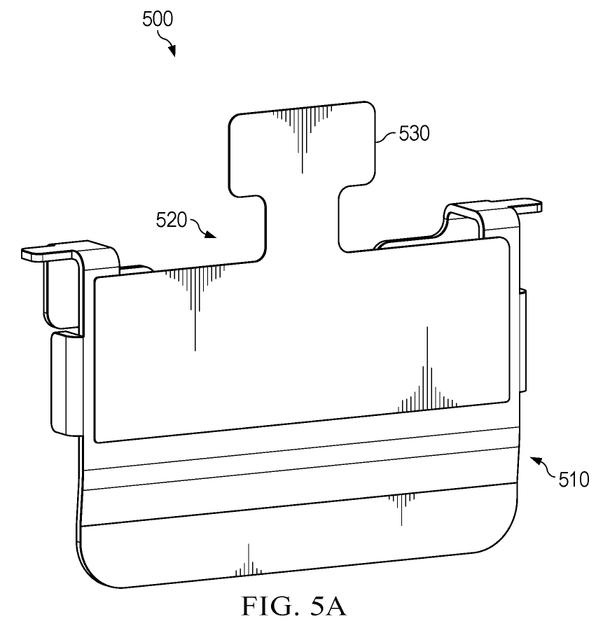

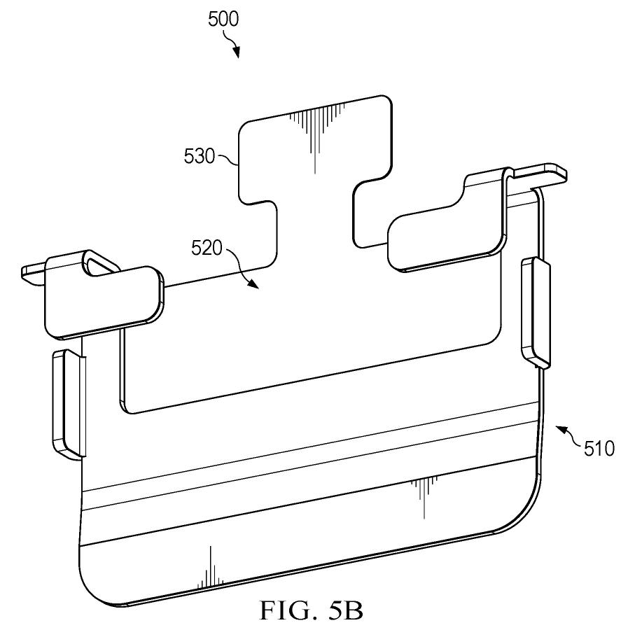

FIGS. 5A and 5B, generally referred to as FIG. 5, show views of a cable management component 500. More specifically, FIG. 5A shows a front perspective view of a cable management component 500. FIG. 5B shows a rear perspective view of a cable management component 500. In certain embodiments, cable management component 500 corresponds to the cable management component of the cable management system 150.

In certain embodiments, the cable routing component 500 includes a mounting bracket portion 510, a cable routing portion 520, or a combination thereof. In certain embodiments, the cable routing portion 520 is physically coupled to the mounting bracket portion 510. In certain embodiments, the mounting bracket portion 510 is configured to mount to a side of a chassis when the cable management component 500 is in a cable management configuration. In certain embodiments, the cable routing portion 520 is configured to slide along a cable when the cable management component 500 moves between a stowed configuration and a cable management configuration.

In certain embodiments, the cable routing portion 520 includes a pull tab 530 for lifting the cable routing component 500 onto the chassis wall when moving the cable routing component from the stowed configuration to the cable management configuration.

In certain embodiments, the mounting bracket portion 510 is constructed from metal. In certain embodiments, the cable routing portion 520 is constructed from a thinner material than that of the mounting bracket portion 510. In certain embodiments, the cable routing portion 520 is constructed from a polyester film such as a polyethylene terephthalate (PET) type material. In certain embodiments, the mounting bracket portion 510 surrounds the cable routing portion 520 along a first side edge, a second side edge, a bottom edge, or a combination thereof. The cable routing portion 520 provides extra clearance for a cable in a hemmed/jogged area on a chassis side wall. In certain embodiments, the cable routing portion 520 is attached to the mounting bracket portion 510 via adhesive. In certain embodiments, a first side edge, a second side edge, a bottom edge, or a combination thereof of the cable routing portion 520 are attached to the mounting bracket portion 510 via adhesive.

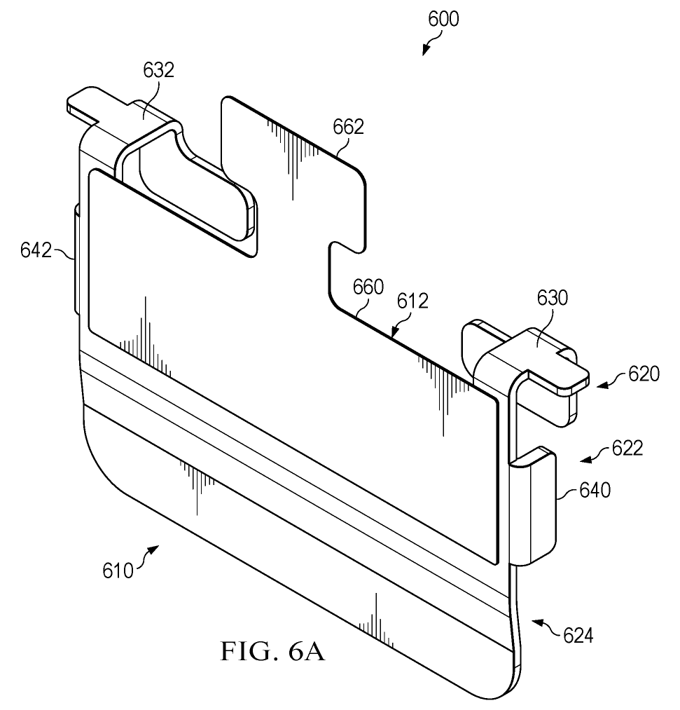

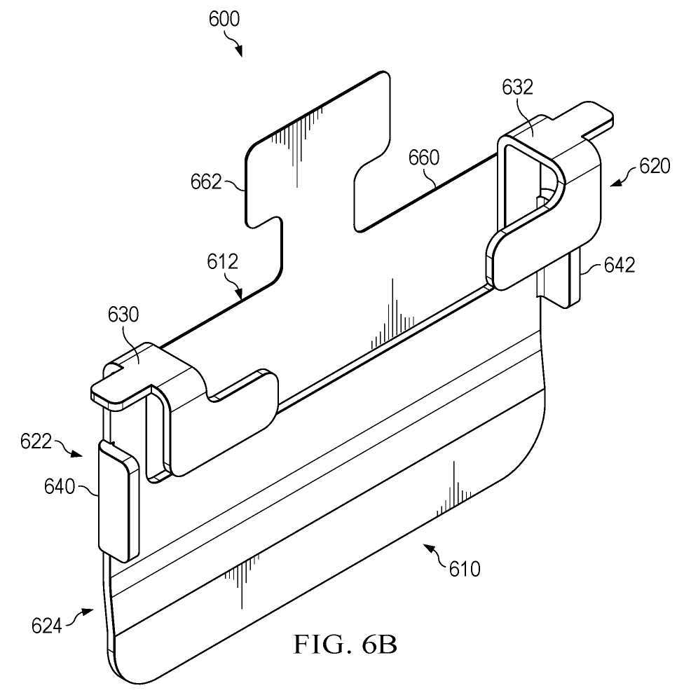

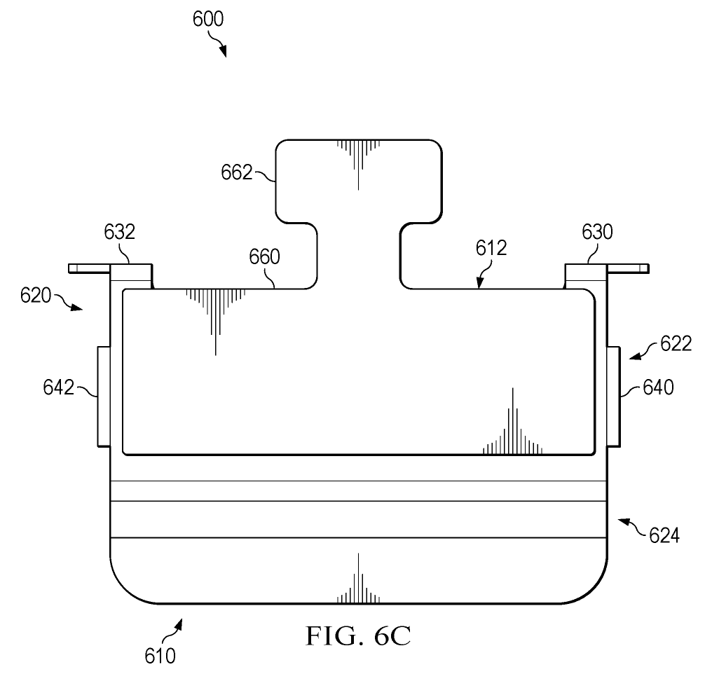

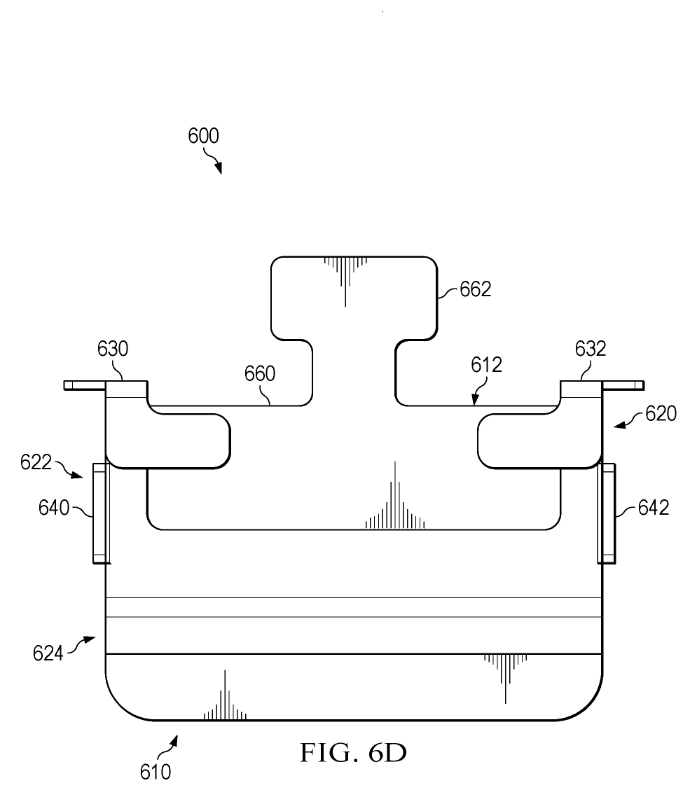

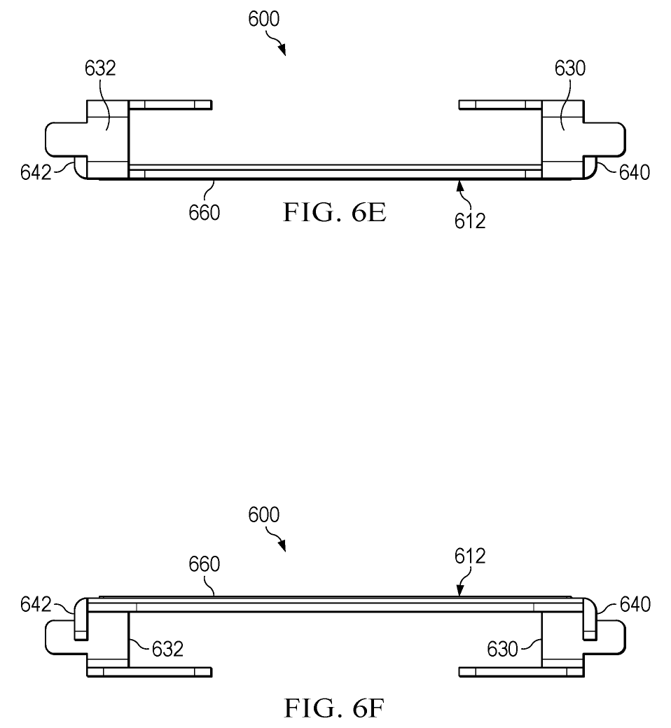

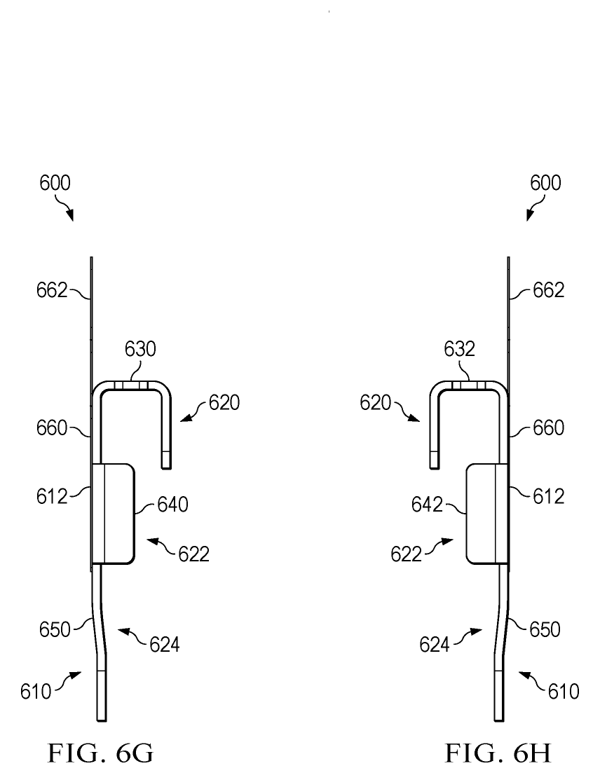

FIGS. 6A, 6B, 6C, 6D, 6E, 6F, 6G and 6H show views of a cable management component 600. More specifically, FIG. 6A shows a front perspective view of a cable management component 600. FIG. 6B shows a rear perspective view of a cable management component 600. FIG. 6C shows a front view of a cable management component 600. FIG. 6D shows a rear view of a cable management component 600. FIG. 6E shows a top view of a cable management component 600. FIG. 6F shows a bottom view of a cable management component 600. FIG. 6G shows a right view of a cable management component 600. FIG. 6F shows a left view of a cable management component 600. In certain embodiments, cable management component 600 corresponds to the cable management component of the cable management system 150. In certain embodiments, the cable routing component 600 includes a mounting bracket portion 610, a cable routing portion 612, or a combination thereof.

In certain embodiments, the mounting bracket portion 610 includes a hanger portion 620, a cable channel portion 622, a guide portion 624, or a combination thereof. In certain embodiments, the hanger portion 620 is configured to mount to a side of a chassis when the cable management component 600 is in a cable management configuration. In certain embodiment, the cable channel portion 622 is configured to provide a cable channel via which a cable is guided when moving between a stowed configuration and a cable management configuration. In certain embodiments, the guide portion is configured to guide the cable management component 600 along an edge of an HPM when moving from a cable management configuration to a stowed configuration. In certain embodiments, the hanger portion 620, the cable channel portion 622, the guide portion 624, or a combination thereof, are constructed from a single piece of material.

In certain embodiments, the hanger portion 620 includes a first side hanger element 630, a second side hanger element 632, or a combination thereof. In certain embodiments, the first side hanger element 630 is positioned along a top right edge of the mounting bracket portion 610. In certain embodiments, the first side hanger element 630 is positioned along a top right edge of the hanger portion 620. In certain embodiments, the second side hanger element 632 is positioned along a top left edge of the mounting bracket portion 610. In certain embodiments, the second side hanger element 632 is positioned along a top left edge of the hanger portion 620. In certain embodiments, the first side hanger element 630, the second side hanger element 632, or a combination thereof, are configured to mount to a side of a chassis when the cable management component 600 is in a cable management configuration.

In certain embodiments, the cable channel portion 622 includes a first side channel element 640, a second side channel element 642, or a combination thereof. In certain embodiments, the first side channel element 640 is positioned along a right edge of the mounting bracket portion 610. In certain embodiments, the first side channel element 640 is positioned along a right edge of the cable channel portion 622. In certain embodiments, the second side channel element 642 is positioned along a left edge of the mounting bracket portion 610. In certain embodiments, the second side channel element 642 is positioned along a left edge of the cable channel portion 622. In certain embodiments, the first side channel element 640, the second side channel element 642, or a combination thereof, are configured to provide a cable channel via which a cable slides when moving between a stowed configuration and a cable management configuration.

In certain embodiments, the guide portion 624 includes an angled element 650. In certain embodiments, the angled element 650 is configured to guide the cable management component 600 along an edge of an HPM when moving from a cable management configuration to a stowed configuration.

In certain embodiments, the cable routing portion 612 includes a cable routing element 660, a pull tab 662, or a combination thereof. In certain embodiments, the cable routing element 660 is configured slide along a cable when the cable management component 500 moves between a stowed configuration and a cable management configuration

In certain embodiments, the pull tab 662 facilitates lifting the cable routing component 600 onto the chassis wall when moving the cable routing component from the stowed configuration to the cable management configuration. In certain embodiments, the mounting bracket portion 610 surrounds the cable routing element 660 along a first side edge, a second side edge, a bottom edge, or a combination thereof. The cable routing portion 612 provides extra clearance for a cable in a hemmed/jogged area on a chassis side wall. In certain embodiments, the cable routing portion 612 is attached to the mounting bracket portion 610 via adhesive. In certain embodiments, a first side edge, a second side edge, a bottom edge, or a combination thereof of the cable routing element 660 are attached to the mounting bracket portion 610 via adhesive. In certain embodiments, the cable routing element 660 and the pull tab 662 are constructed from a single piece of material.

In certain embodiments, the mounting bracket portion 610 is constructed from metal. In certain embodiments, the cable routing portion 612 is constructed from a thinner material than that of the mounting bracket portion 610. In certain embodiments, the cable routing portion 612 is constructed from a polyester film such as a polyethylene terephthalate (PET) type material.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A cable management component of a cable management system for an information handling system, comprising:
a mounting bracket portion, the mounting bracket portion being configured to mount to a side of a chassis when the cable management component is in a cable management configuration; and;
a cable routing portion physically coupled to the mounting bracket portion, the cable routing portion being configured to slide along a cable when the cable management component moves between a stowed configuration and the cable management configuration.

2. The cable management component of claim 1, wherein:
the mounting bracket portion includes a hanger portion and a cable channel portion, the mounting bracket portion being configured to mount to the side of a chassis when the cable management component is in the cable management configuration, the cable channel portion being configured to provide a cable channel, the cable channel providing a cable channel, the cable being guided within the cable channel when the cable management component moves between the stowed configuration and the cable management configuration.

3. The cable management component of claim 2, wherein:
the mounting bracket portion further includes a guide portion, the guide portion being configured guide the cable management component along an edge of an HPM when the cable management component moves from the cable management configuration to the stowed configuration.

4. The cable management component of claim 3, wherein:
the hanger portion, the cable channel portion and the guide portion are constructed from a single piece of material.

5. The cable management component of claim 1, wherein:
the cable routing portion includes a cable routing element and a pull tab, the cable routing portion being configured to slide along the cable when the cable management component moves between the stowed configuration and the cable management configuration, the pull tab facilitating lifting of the cable management component onto the side of the chassis.

6. The cable management component of claim 5, wherein:
the cable routing element and the pull tab are constructed from a single piece of material.

7. A cable management system for use in an information handling system comprising:
a chassis;
a cable; and,
a cable management component, the cable management component comprising:
a mounting bracket portion, the mounting bracket portion being configured to mount to a side of the chassis when the cable management component is in a cable management configuration; and;
a cable routing portion physically coupled to the mounting bracket portion, the cable routing portion being configured to slide along the cable when the cable management component moves between a stowed configuration and the cable management configuration.

8. The cable management system of claim 7, wherein:
the mounting bracket portion includes a hanger portion and a cable channel portion, the mounting bracket portion being configured to mount to the side of a chassis when the cable management component is in the cable management configuration, the cable channel portion being configured to provide a cable channel, the cable channel providing a cable channel, the cable being guided within the cable channel when the cable management component moves between the stowed configuration and the cable management configuration.

9. The cable management system of claim 8, wherein:
the mounting bracket portion further includes a guide portion, the guide portion being configured guide the cable management component along an edge of an HPM when the cable management component moves from the cable management configuration to the stowed configuration.

10. The cable management system of claim 9, wherein:
the hanger portion, the cable channel portion and the guide portion are constructed from a single piece of material.

11. The cable management system of claim 7, wherein:
the cable routing portion includes a cable routing element and a pull tab, the cable routing portion being configured to slide along the cable when the cable management component moves between the stowed configuration and the cable management configuration, the pull tab facilitating lifting of the cable management component onto the side of the chassis.

12. The cable management system of claim 11, wherein:
the cable routing element and the pull tab are constructed from a single piece of material.

13. A system comprising:
a chassis;
a cable contained within the chassis;
a high performance module contained within the chassis; and,
a cable management system, the cable management system comprising:
a mounting bracket portion, the mounting bracket portion being configured to mount to a side of a chassis when the cable management component is in a cable management configuration; and;
a cable routing portion physically coupled to the mounting bracket portion, the cable routing portion being configured to slide along a cable when the cable management component moves between a stowed configuration and the cable management configuration.

14. The system of claim 13, wherein:
the mounting bracket portion includes a hanger portion and a cable channel portion, the mounting bracket portion being configured to mount to the side of a chassis when the cable management component is in the cable management configuration, the cable channel portion being configured to provide a cable channel, the cable channel providing a cable channel, the cable being guided within the cable channel when the cable management component moves between the stowed configuration and the cable management configuration.

15. The system of claim 14, wherein:
the mounting bracket portion further includes a guide portion, the guide portion being configured guide the cable management component along an edge of an HPM when the cable management component moves from the cable management configuration to the stowed configuration.

16. The system of claim 15, wherein:
the hanger portion, the cable channel portion and the guide portion are constructed from a single piece of material.

17. The system of claim 16, wherein:
the cable routing portion includes a cable routing element and a pull tab, the cable routing portion being configured to slide along the cable when the cable management component moves between the stowed configuration and the cable management configuration, the pull tab facilitating lifting of the cable management component onto the side of the chassis.

18. The system of claim 17, wherein:
the cable routing element and the pull tab are constructed from a single piece of material.
